(19) United States
(12) Patent Application Publication
(10) Pub. No.: US 2013/0148307 A1
(43) Pub. Date: Jun. 13, 2013

(54) METHOD FOR PRODUCING AND ELECTRICAL CIRCUIT AND ELECTRICAL CIRCUIT

(71) Applicant: Eckart Geinitz, Pfullingen (DE)

(72) Inventor: Eckart Geinitz, Pfullingen (DE)

(73) Assignee: ROBERT BOSCH GMBH, Stuttgart (DE)

(21) Appl. No.: 13/818,725

(22) PCT Filed: Jul. 13, 2011
(86) PCT No.: PCT/EP2011/061979

§ 371 Date: Feb. 25, 2013

(30) Foreign Application Priority Data
Aug. 25, 2010 (DE) 10 2010 039 728.8

(51) Int. Cl. H05K 3/30; H05K 1/02

(52) U.S. Cl. CPC H05K 3/303; H05K 1/0204
USPC 361/720; 29/832; 29/840

(57) ABSTRACT

The invention relates to a method for producing an electrical circuit. A prefabricated substrate is provided, said substrate having a first and a second conductor layer and having a dielectric between the first and the second conductor layers. According to the invention, the first conductor layer is multiple times thicker than the second conductor layer. At least one component to be cooled is mounted on the first conductor layer of the prefabricated substrate, forming a heat-transferring connection between the component and the first conductor layer. The invention further relates to an electrical circuit produced in said manner. According to the invention, the electrical circuit comprises a prefabricated substrate which is produced having a first and a second conductor layer and a dielectric located therebetween. According to the invention, the first conductor layer is multiple times thicker than the second conductor layer. At least one component to be cooled is mounted on the first conductor layer. According to the invention, there is a heat-transferring connection between the component and the first conductor layer.

### BACKGROUND OF THE INVENTION

The use of heat sinks for the removal of dissipated heat of electrical or electronic components is known, said heat sinks being connected in a heat-conducting manner to the components via a printed circuit board or a substrate. The heat is initially transferred from the heat source, i.e. the components, to the printed circuit board to which said components are mounted. The heat is then transferred from the circuit board to the heat sink.

So-called insulated metal substrates (IMS) comprise a thick metal plate, which is mounted to the heat sink, for improved heat dissipation, whereas a copper cladding, which is connected to the metal plate via a dielectric, provides conductor tracks for the electrical components to be mounted thereon. The copper cladding is of thin design (max. 300 μm) so that the conductor tracks can be formed by structuring said copper cladding, in particular by means of photolithography and subsequent etching. A disadvantage which necessarily occurs in the case of this arrangement is then that the copper cladding, to which the components are mounted, cannot sufficiently spread the heat on account of the small thickness thereof. This is especially true because the proximate dielectric has a low thermal conductivity due to the nature of the material. When the thermal load is high, a concentrated heat accumulation (“hot spot”) occurs at the mounting location of the components as a result of the insulation effect of the dielectric and as a result of the low amount of heat dissipation by the copper cladding.

In the German patent publication DE 103 31 857 B4, a power semiconductor assembly is described in which a thicker metal plate supports a power semiconductor (=heat source). The metal plate is disposed on a conjoint aggregate consisting of an insulating resin layer and a thinner metal layer, wherein said conjoint aggregate is placed onto the metal plate with the insulating layer leading and is connected to the metal plate by means of a pressure treatment using the application of heat, whereby said metal plate is already embedded in casting material. In so doing, the aggregate protrudes far beyond the thicker metal plate and is furthermore connected to the casting material in edge regions.

The step-by-step manufacturing process provided in the aforementioned manner requires numerous layer connection steps, wherein at least the attachment of the aggregate to the remaining circuit (as one of these steps) is executed with circuit components that are already completely fitted. For that reason, pressure and temperature are limited, the circuit being further stressed by pressure and temperature. In addition, the desired temperature-resistant arrangement cannot be achieved with the step-by-step attachment of the layers to each other because residual air, which creates a hot spot, can be present between the layers as a result of the individual manufacturing steps for said layers. Finally the individual components are not standard units that can be manufactured in bulk; and therefore aside from the costs of the complex manufacturing process, the unit, or respectively component, costs are also high.

### SUMMARY OF THE INVENTION

It is the aim of the invention to provide in this case an electrical circuit and a manufacturing process which both allow for a simpler and more cost effective manufacture and which both facilitate an increase in heat dissipation.

The invention makes it possible to use cost effective standard components and to reduce the number of steps required in the manufacturing process. In addition, a more resilient and efficient heat dissipation is produced. The circuit produced is furthermore more fail-safe because the circuit components are not exposed to any heat or pressure when the heat dissipation components are being disposed. Finally, the invention allows the dielectric strength of the heat dissipating layers to be tested without other components being able to disturb the disruptive discharge test or said disruptive discharge test endangering the electrical components of the circuit.

According to the invention, a prefabricated substrate is used, which comprises a first and a second conductor layer that are separated by a dielectric. The first conductor layer is multiple times thicker than the second conductor layer and serves to directly receive heat from a component mounted thereon, which represents a heat source and is to be cooled down. The heat being generated is widely dissipated on account of the large thickness of the first conductor layer. Said first conductor layer essentially facilitates heat transfer. The second conductor layer particularly serves to protect the dielectric and can where applicable serve as circuitry and be structured with conductor tracks. As a result of the protection by the second layer, it is possible for the dielectric to be embodied as a thin insulating layer, which particularly due to the small thickness thereof facilitates a high thermal conductivity. Said second layer protects during manufacture (and during subsequent assembly) the dielectric from mechanical influences. The dielectric proximate to the first conductor layer can transfer the widely distributed heat flow to the second conductor layer using a large through surface. The second conductor layer serves to contact a heat sink (or a thermal bridge which leads to a heat sink). When manufacturing the inventive circuit while using the inventive method for manufacturing said circuit, a prefabricated substrate is assumed, the layer structure of which has already been completed. Such a substrate is produced according to usual methods for manufacturing circuit boards or substrates, wherein pressures and temperatures are used during manufacture (in the absence of further components) which only take the properties of the substrate into account. Higher temperatures, pressures or other manufacturing parameters can particularly be used, which would adversely affect other components like casting materials for embedding the circuit, semiconductor devices or thermally conductive pastes.

The first conductor layer is a metal plate, in particular consisting of Cu, Al, a Cu alloy, an Al alloy or another heat conducting material. The first conductor layer is used as a support. Said first conductor layer can have a thickness of 0.5-10 mm, 0.8-8 mm, 1-5 mm or 1-3 mm. The thickness of the first conductor layer is particularly at least 0.5, 0.8, 1 or 2 mm. This facilitates a high dissipation of the heat which directly emanates from the component to be cooled that is directly mounted on said first conductor layer.

The second conductor layer is a metal cladding, in particular consisting of copper. The thickness of the second conductor layer is 0.03-0.45 mm, in particular 0.07-0.3 mm. The thickness of the second conductor layer is not more than 0.4 or 0.2 mm. Even if the invention does not necessarily provide structures in the second conductor layer, the thickness is nevertheless selected such that typical photolithographic procedures or milling procedures for structuring said layer are possible in order to be able to draw on components, which are also used for other purposes and which can therefore be advantageously manufactured as bulk goods.

The dielectric consists of an electrically insulating material, in particular of an epoxy resin layer or of another heat conducting, insulating adhesive. The thickness of the dielectric, which is embodied as a general layer, is preferably 0.03-0.3 mm, in particular 0.075-0.2 mm. The dielectric is constituted to transition from a fluid state into an elastic state during the manufacture of the substrate by means of chemical or physical hardening or solidification due to cooling. The first conductor layer, the dielectric and the second conductor layer are pressed together during manufacture of the substrate, while the dielectric is fluid. A tough, at least partially elastic connection between the conductor layers is produced by the dielectric; thus enabling the substrate used according to the invention to be mechanically robust. The substrate used according to the invention is further characterized in that the layers are pressed together under a vacuum (and where applicable heated) during the manufacture thereof. As a result, the substrate has a good thermal conductivity through the dielectric because residual air between all of the layers is removed. In so doing, hot spots are prevented. Furthermore, the fact that the substrate can (in contrast to ceramic based circuit boards) absorb mechanical loads without incurring damage results from the material selection for the substrate (in particular from the elastic properties of the dielectric).

The electrical circuit provided according to the invention is preferably a power circuit, in particular for the automotive field. The components to be cooled are preferably power semiconductors, for example: transistors, IGBTs, diodes, FETs, bipolar transistors, thyristors, TRIACs or perhaps other components with high power dissipation such as resistors, chokes or transformers. The components can furthermore be components with high heat emission such as, for example, processors or controllers. The invention is used particularly for control circuits, output stages or driver circuits in the automotive field, for example, for engine management systems or electric drive control systems.

The invention therefore provides a method for producing an electrical circuit, wherein a prefabricated substrate having a first and a second conductor layer as well as a dielectric is initially provided. The substrate is situated between the first and the second conductor layer. The first conductor layer is multiple times thicker than the second conductor layer. The multiple can range from 1.2 to 350 or preferably from 3 to 100 and is generally a real number. At least one component to be cooled is mounted on the first conductor layer of the prefabricated substrate. A heat-transferring connection between the component and the first conductor layer is configured as a result of the mounting. Component and first conductor layer are directly connected to one another, i.e. by means of direct contact, preferably via a direct physical contact and/or a cohesive connection such as a soldered connection, in which a thin layer of solder establishes the direct contact. Certain embodiments can require that the contact is provided via a thin layer of thermally conductive material (i.e. thermally conductive paste or a thermally conductive pad). Due to the high thermal conduction via such contacts, the previously described contacts can be considered to be direct contacts.

According to a particular aspect of the invention, the prefabricated substrate is provided as an interconnected (preferably under a vacuum) stack of the first conductor layer, the dielectric and the second conductor layer. In a variant that is easy to implement, the substrate is provided as a so-called metal core printed circuit board, wherein said substrate can also be provided as an IMS (insulated metal substrate) or as a metal carrier having a printed circuit board laminated under a vacuum thereon. Such IMS substrates are known extensively and are manufactured in large piece numbers at low costs. Said IMS substrates are used as starting material for the inventive circuit or the inventive method. Instead of the customary practice, in which the components are mounted on the thinner second layer, provision is made according to the invention for the components to be cooled to be mounted on the thicker conductor layer; thus enabling said conductor layer to dissipate the heat in an unimpeded manner over the entire thickness of the first conductor layer. The invention recognized that the customary practice of mounting components can lead to a concentrated heat accumulation during a transfer of the still undissipated heat flow across the dielectric. This disadvantage is overcome according to the invention by the components being mounted on the thicker, first conductor layer. A main aspect of the invention is therefore the use of a customary IMS in reversed manner, wherein the components are mounted on the thicker conductor layer. The thinner layer, which is used in the prior art for conductor tracks, serves according to the invention as a contact surface for heat sinks.

Provision is made in a further embodiment of the method according to the invention for the mounting of the at least one component to be cooled to further comprise: forming an electrical contact between the component and the first conductor layer, in particular by soldering a contact of said component facing the first conductor layer onto the surface of the first conductor layer facing said component. Other methods for establishing an electrical contact can also be used, e.g. terminals, flanges or a screwed contact. Aside from heat dissipation, the first, thicker conductor layer therefore also serves to electrically contact the components. For that reason, provision can also be made for establishing an electrical connection to the first conductor layer, for example, by means of a soldered connection, by means of a contact pressing against said first conductor layer or by means of bonding. A resilient conductor bracket can especially be used, which is pressingly disposed onto the first conductor layer or on an upper contact surface of the component.

Provision is furthermore made for the substrate to be structured prior to or after mounting the at least one component by separating individual substrate sections through the entire thickness of the substrate. The substrate is therefore divided into individual, initially physically separated substrate sections. Using this procedural approach, individual electrical connections are possible as they otherwise are provided by conductor tracks. For that reason, an electrical connection is further formed between the substrate section on the one hand and an electrical contact interface or a further substrate section. The measures mentioned above make provision for the connections, in particular by means of a soldered bracket or one resiliently held in contact, which contacts the first conductor layer of the substrate section or an upper contact of the component and is additionally connected in the same manner to a contact point of an electrical interface or to a first conductor layer or to an upper contact of a component of a further substrate section. At least one of the substrate sections supports at least one component.

An electrical connection can be established between the at least one component and an electrical contact interface or between the component and a further component mounted on the first conductor layer by means of bonding at least one conductor, said bonding performed by means of soldering or by means of soldering on a conductor, in particular a metal bridge. The contact interface corresponds to the electrical interface for connecting external components.

The method can furthermore provide that at least one part of the substrate and the at least one component are cast integral (by embedding in an injection-moldable plastic, in particular by means of an injection molding process). Provision is especially made for this casting process if substrate sections are used, wherein the substrate sections are cast integral after mounting the at least one component. According to this aspect, the inventive circuit therefore comprises a casting compound in which at least one part of the substrate (in particular the first layer) and the at least one component are embedded. If connections are used between substrate (substrate section) and an electrical interface or between substrate sections, said connections are or have been likewise preferably cast integral.

The individual substrate sections of the substrate are separated from one another by stamping, sawing, cutting, laser cutting or by scoring (preferably on both sides) and snapping techniques. Provision is furthermore made alternatively or in combination herewith for a heat sink, to which the individual substrate sections are mounted. Heat-transferring connections between the second conductor layers of the substrate and that of the heat sink are formed by means of the mounting. Provision can be made for the heat sink to consist of a metal plate, on which some or all of the substrate sections of the circuit are disposed. The heat-transferring connection is provided by direct contact between the second conductor layer and the heat sink (where applicable supported by a layer consisting of thermally conductive paste). Provision can likewise be made for said heat sink to consist of a cooling element comprising cooling fingers, said cooling element having a contact surface for heat absorption and the second conductor layer being connected to said contact surface in a heat-transferring manner.

In an alternative embodiment, only the first conductor layer and not the entire substrate is structured, i.e. divided up into sections that are electrically separated from one another, by means of milling or by providing a prefabricated substrate which already has a structured first conductor layer. The individual sections of the first conductor layer are disposed in fixed positions with respect to each other by means of the dielectric and the second conductor layer. Because the structuring can depend on the circuit, this variant is particularly provided for series manufacturing of the same (or similar) circuits.

According to a further embodiment, an edge region of the second conductor layer is removed, in particular by etching or milling. The second layer is removed in the edge region across the entire thickness thereof. As a result, an overhang of the dielectric vis-à-vis the second conductor layer is produced in the edge region. The inventive circuit has likewise an edge region, whereat the dielectric protrudes laterally beyond the second circuit layer and consequently forms an overhang. This enables the reliable electrical separation of the first conductor layer from the second conductor layer (or the heat sink).

According to a further embodiment, the prefabricated substrate is provided as a substrate, the dielectric strength of which has been measured, for example within the scope of the final inspection of a preceding substrate manufacturing process, the final product of which is the substrate used according to the invention. In so doing, the rejection rate of the inventive manufacturing process is reduced. The provision of the substrate can alternatively comprise: determining the dielectric strength by applying a test voltage between the first and the second conductor layer and acquiring a measuring current, preferably prior to mounting the components. As a result, the layer structure can already be tested during the manufacture of the electrical circuit, wherein faulty substrates can be discarded prior to mounting the components (and prior to the embedding process). In so doing, costs are reduced by discarding said faulty substrates.

The invention is furthermore implemented with the aid of an electrical circuit. The features of the circuit correspond to the associated features of the circuit components as said components are described above or respectively as they arise from the procedural approaches described above. This applies especially to the substrate, the component, substrate sections, etc. The inventive electrical circuit comprises a prefabricated substrate which is produced having a first and a second conductor layer as well as a dielectric located therebetween. The substrate obtains a high thermal conductivity and elasticity by means of the prefabrication (performed under manufacturing parameters, which could not be adhered to in the case of fitted components). In addition, the components are not damaged by pressure or thermal load (as they are not subjected to the manufacturing parameters of the substrate). The first conductor layer is multiple times thicker than the second conductor layer. The circuit further comprises at least one component to be cooled, which is mounted on the first conductor layer. A heat-transferring connection is provided between the component and the first conductor layer, preferably by means of direct contact, which is provided by a soldered connection, i.e. a thin layer of solder between the component and the first conductor layer. The direct contact can especially be established by direct physical contact. As an alternative, the contact can be reinforced by a thermal paste which provides a thermally conductive layer. The direct contact provides a high degree of heat transfer between component and the first conductor layer.

Provision is made in an embodiment of the inventive electrical circuit for the substrate to be divided into a plurality of individual, separated substrate sections. A component to be cooled is disposed on at least two of the substrate sections. The substrate sections are fastened to a heat sink. Said substrate section is connected in a heat-transferring manner to the second conductor layer of the substrate sections (preferably via direct contact and where applicable reinforced by thermally conductive paste). The substrate sections as well as the at least one component are embedded in a casting compound. The casting compound consists of an electrically insulating plastic material, preferably of an injection-moldable plastic material. Electrical connections (metal bridges, soldered connections, bonded connections or a combination of these) can be provided in the circuit as described above in order to connect the substrate sections among one another or to connect a substrate section to a contact interface (as described above).

The first conductor layer can alternatively be divided into sections which are electrically separated from one another, wherein the sections are firmly connected to the dielectric by mechanical means. The first conductor layer can together with the dielectric and the second conductor layer be embodied in the form of a lead frame.

### BRIEF DESCRIPTION OF THE DRAWINGS

FIG. 1 shows an exemplary embodiment of an inventive electrical circuit in cross-sectional representation.

### DETAILED DESCRIPTION

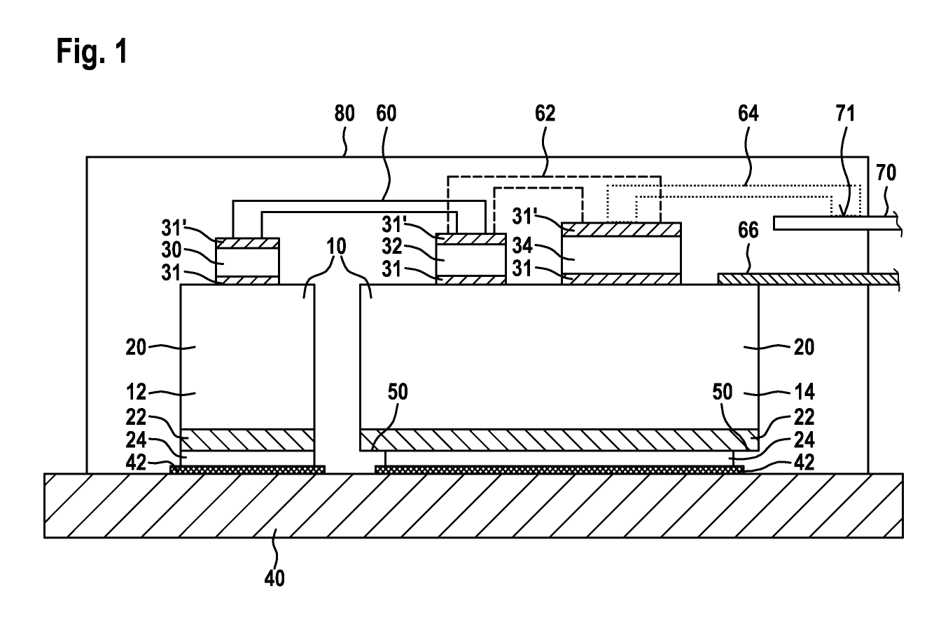

The exemplary embodiment of the inventive circuit depicted in FIG. 1 comprises a substrate 10, which is divided into two sections 12, 14. The substrate comprises a first conductor layer 20, a dielectric 22 in the shape of a layer and a second conductor layer 24. Components 30, 32, 34 are mounted on the first conductor layer 20 by means of soldered connections. The second conductor layer 24 of all of the sections is fastened via soldered connections 42 to a common heat sink in the form of a metal plate 40, a soldered connection 42 being provided for each section. An alternative, heat-transferring connection 42 would be an electrically insulating, heat-transferring connection in the form of a layer consisting of thermally conductive paste.

The second conductor layer 24 is undercut with respect to the dielectric, and therefore overhangs 50 are provided.

Each component 30-34 has an upper and a lower contact surface. The lower contact surface 31 is soldered directly onto the first conductor layer 20 in order to provide a heat-transferring connection to the latter. The upper contact surface 31′ of the components 32-34 is connected via contact bridges made of metal. The contact bridge 60 connects the upper contact 31′ of the component 30 to the upper contact 31′ of the component 32, wherein the two components 30 and 32 are provided on different sections 12, 14 of the substrate 10. The contact bridge 62, depicted with a dashed line, connects the upper contact surface 31′ of the component 30 to the upper contact surface 31′ of the component 32, wherein the two components 30 and 32 are provided on the same section 14 of the substrate 10. In the event that the lower contacts 31 of the components 32 and 34 are electrically active, said lower contacts are then connected to one another via the first conductor layer 20 and via the soldered connections between the lower contacts 31 of the components 32 and 34 of the first conductor layer 22 of the section 14.

A further electrical connection is constituted by the contact bridge 64 (depicted with a dotted line) which connects the upper contact 31′ of the component 34 to a contact interface 70. The contact bridge 64 can (as is the case with other contact bridges of the circuit) be connected to the respective contact surfaces via soldered connections or can have elastic properties, being pressed downwards towards the substrate by an element, which is not depicted, and being connected to the contact surfaces via the resulting pressed contact. The contact interface 70 has a contact surface 71 for contacting the bridge and extends through an outer side of the circuit for the termination of external components (sensors, power supply . . . ). The components can further comprise control inputs (not depicted), which are particularly contacted via bonding connections. The electrical connections depicted in FIG. 1 (contact bridges 60-66) are high current connections, which are equipped for transporting power currents, in particular by means of the cross-section thereof (and material thereof, Cu or Al). Finally a further electrical connection is in the form of a contact bridge 66, which comprises a contact surface that is directly attached to the first conductor layer 20 of the section 14 of the substrate 10. The contact bridge can be connected to the first conductor layer 20 by means of a soldered connection.

The circuit is embedded in a casting material 80, wherein aside from the contact interface 70 and the contact bridge 66 (as well as the metal plate 40) all components are embedded via the casting material 80. The contact interface 70 and the contact bridge 66 protrude through the outer side of the circuit, i.e. through the casting material. In addition, the metal plate 40 has a lower side which is not covered by the casting material, wherein the remaining circuit components are disposed on the opposite upper side.

When manufacturing the circuit pursuant to FIG. 1, provision is initially made for the substrate 10 which is cut in order to form the sections 12 and 14. The components are fastened to the substrate (prior to or preferably after cutting said substrate) and said substrate, already divided into sections, is fastened to the metal plate 4 which serves as a connecting support for the sections. The contact bridges 60-66 and the contact interface 70 are fastened to the components or to the first conductor layer. The components 30-34, the contact bridges 60-66 and the contact interface 70 are fastened by means of soldering. After fastening the components 30-34, the contact bridges 60-66 and the contact interface 70, the circuit is embedded in the casting material 80. In addition, the metal plate 40 is attached in a heat-transferring manner to the second conductor layer 24 by means of thermally conductive paste or thermally conductive adhesive 42. The metal plate 40 thus forms the heat sink. The embedding is preferably performed after the metal plate has been attached to the second conductor layer in a heat-transferring manner. During the embedding process, the external regions of the contact bridge 66 and the contact interface 70 (i.e. regions, which extend away from the subsequent outer side of the circuit) are not within a mold, into which the material is poured. These regions can alternatively be exposed after the embedding process.

1. A method for producing an electrical circuit, which comprises the steps: providing a prefabricated substrate (10) having a first and a second conductor layer (20, 24) as well as a dielectric (22), which is provided between the first and the second conductor layer, the first conductor layer (20) being multiple times thicker than the second conductor layer (24); and mounting of at least one component (30-34) to be cooled on the first conductor layer (20) of the prefabricated substrate, forming a heat-transferring connection between the component and said first conductor layer.

2. The method according to claim 1, wherein the prefabricated substrate (10) is provided as a stack interconnected under a vacuum of the first conductor layer (20), the dielectric (22) and the second conductor layer (24), as a metal core printed circuit board or insulated metal substrate, IMS, or as a metal carrier having a printed circuit board laminated under a vacuum thereon.

3. The method according to claim 1, wherein the mounting of the at least one component (30-34) to be cooled further comprises: forming an electrical contact between the component (30-34) and the first conductor layer (20).

4. The method according to claim 1, wherein the substrate (10) is structured prior to or after mounting the at least one component (30-34) by separating individual substrate sections (12, 14) through an entire thickness of the substrate, wherein at least one of the substrate sections supports at least one component, and further comprising forming an electrical connection between a substrate section (14) and an electrical contact interface (70) or a further substrate section (12) and the substrate sections are embedded after mounting the at least one component.

5. The method according to claim 4, wherein the individual substrate sections (12, 14) are separated from one another by stamping, sawing, cutting, laser cutting or by scoring and snapping techniques, wherein the individual substrate sections are mounted on a heat sink (40), forming heat-transferring connections (42) between the second conductor layers (24) of the substrate and that of the heat sink (40).

6. The method according to claim 1, wherein an electrical connection is established between the at least one component (30-34) and an electrical contact interface (70) or between the component (32) and a further component (34) mounted on the first conductor layer by bonding at least one conductor, by soldering or by soldering on a conductor.

7. The method according to claim 1, wherein furthermore an edge region of the second conductor layer is removed, and an overhang (50) of the dielectric (22) with respect to the second conductor layer (24) is produced in the edge region.

8. The method according to claim 1, wherein the prefabricated substrate (10) is provided as a substrate (10), the dielectric strength of which has been measured.

9. An electrical circuit, comprising a prefabricated substrate (10), which is produced having a first and a second conductor layer (20, 24) and a dielectric (22) located therebetween, wherein the first conductor layer (20) is multiple times thicker than the second conductor layer (24), and comprising at least one component (30-34) to be cooled, which is mounted on the first conductor layer (20), a heat-transferring connection being provided between the component (30-34) and said first conductor layer (20).

10. The electrical circuit according to claim 9, wherein the substrate (10) is divided into a plurality of individual, separated substrate sections (12, 14), wherein at least one component (30-34) to be cooled is disposed on at least two of the substrate sections, the substrate sections are mounted on a heat sink (40) which is connected to the second conductor layer (24) of the substrate sections in a heat-transferring manner and the substrate sections (12, 14) as well as the at least one component (30-34) are embedded in a casting compound (80).

11. The method according to claim 1, wherein the mounting of the at least one component (30-34) to be cooled further comprises: forming an electrical contact between the component (30-34) and the first conductor layer (20) by soldering a contact of the component which faces the first conductor layer onto the surface of the first conductor layer which faces the component.

12. The method according to claim 1, wherein an electrical connection is established between the at least one component (30-34) and an electrical contact interface (70) or between the component (32) and a further component (34) mounted on the first conductor layer by bonding at least one conductor, by soldering or by soldering on a metal bridge (60-64).

13. The method according to claim 1, wherein furthermore an edge region of the second conductor layer is removed by etching or milling, and an overhang (50) of the dielectric (22) with respect to the second conductor layer (24) is produced in the edge region.

14. The method according to claim 1, wherein providing the substrate comprises: determining the dielectric strength by applying a test voltage between the first and the second conductor layer and acquiring a measuring current.
